(19) United States
(12) Patent Application Publication
(10) Pub. No.: US 2026/0275517 A1
(43) Pub. Date: Sep. 17, 2026

(54) HEAT EXCHANGER FOR VAPORIZER FOR THIN-FILM DEPOSITION

(71) Applicant: ASK CO.LTD., Jeonju-si (KR)

(72) Inventors: Tae Hee KIM, Yongin-si (KR); Seung Won JEOUNG, Jeonju-si (KR); Chang Son Choi, Yongin-si (KR)

(21) Appl. No.: 19/669,711

(22) Filed: May 6, 2026

Related U.S. Application Data
(63) Continuation of application No. PCT/KR2024/002379, filed on Feb. 23, 2024.

(30) Foreign Application Priority Data
Dec. 26, 2023 (KR) 10-2023-0190743

(51) Int. Cl. C23C 16/448; H10P 72/00

(52) U.S. Cl. CPC C23C 16/4486; H10P 72/0402

(57) ABSTRACT

A heat exchanger may include a first housing having an inlet formed through the upper portion thereof such that a liquid droplet aerosol is introduced therein, the introduced liquid droplet aerosol is primarily vaporized in the upper portion, and the remaining liquid droplet aerosol is secondarily vaporized in the lower portion thereof, and the first housing having an outlet formed through the lower portion thereof such that vapor generated by vaporization of the liquid droplet aerosol flows out therethrough. The heat exchanger may also include a second housing inserted into the first housing and having a conical dispersion portion formed in the upper portion thereof such that the liquid droplet aerosol is radially dispersed. The heat exchanger may further include a first heater for heating the first housing while surrounding the first housing, and a second heater located inside the second housing to heat the second housing.

### CROSS-REFERENCE TO RELATED APPLICATIONS

This is a continuation application of International Application No. PCT/KR2024/002379 filed on Feb. 23, 2024, which claims under 35 U.S.C. § 119(e) the benefit of Korean Patent Application No. 10-2023-0190743 filed on Dec. 26, 2023, the entire contents of each of which are incorporated by reference herein.

### STATEMENT REGARDING GOVERNMENT SPONSORED RESEARCH OR DEVELOPMENT

This disclosure was supported by the project listed in Table 1 below.

TABLE 1

| Project Number | RS-2026-25544385 |
|---|---|
| Ministry | Ministry of Trade, Industry and Energy |
| Managing | Korea Institute for Advancement of Technology (KIAT) |
| Agency | |
| Research | Material & Component Technology Innovation (Mass Production |
| Program | Performance Evaluation Support) |
| Research Project | Performance evaluation of DLI type Vaporizer for High-k film |
| Title | deposition |
| Performing | ASK Co., Ltd. |
| Organization | |
| Research Period | 2026 Apr. 1-2027 Dec. 31 |
| Project Number | RS-2024-00508767 |
| Ministry | Ministry of SMEs and Startups |
| Managing | Korea Technology and Information Promotion Agency for SMEs |
| Agency | |
| Research | TIPS R&D Program |
| Program | |
| Research Project | Development of an integrated Vapor Delivery System for vaporizing |
| Title | liquid precursors for semiconductor ALD and CVD processes |
| Performing | ASK Co., Ltd. |
| Organization | |
| Research Period | 2024 Sep. 1-2026 Aug. 31 |
| Project Number | RS-2026-25531281 |
| Ministry | Ministry of Science and ICT |
| Managing | Korea Innovation Cluster |
| Agency | |
| Research | PoC Support Program through Strategic Cooperation |
| Program | |
| Research Project | Development and Evaluation of a domestically produced vaporizer |
| Title | module for mass production of DIPAS liquid precursor for |
| | semiconductor and display ALD processes. |
| Performing | ASK Co., Ltd. |
| Organization | |
| Research Period | 2026 Apr. 1-2027 Dec. 31 |

### BACKGROUND

### Technical Field

The present disclosure relates to a vaporization device for thin-film deposition, and more particularly, to a heat exchanger for a vaporization device for thin-film deposition that vaporizes a droplet aerosol of a liquid precursor to form a vapor.

### Description of Related Technology

In the semiconductor device and display manufacturing process, a thin-film deposition process using a liquid precursor is generally performed. The thin-film is formed by changing the liquid precursor into a gaseous state and depositing it on a substrate in a chamber. A device that supplies the precursor of the gaseous state to the chamber is a vaporization device.

### SUMMARY

One aspect is a heat exchanger that prevents the generation of contaminant particles by compensating for the heat loss occurring at the central portion of the heat exchanger and makes it easy to remove contaminating particles.

Another aspect is a heat exchanger for a vaporization device that includes a first housing in which an inlet through which droplet aerosol flows in is formed at an upper portion, the droplet aerosol flowing in is vaporized firstly at the upper portion, the droplet aerosol remaining after the first vaporization is vaporized secondly at a lower portion, and an outlet through which a vapor formed by vaporizing the droplet aerosol flows out is formed at the lower portion; a second housing inserted into the first housing, and in which a cone-shaped dispersion portion is formed at the upper portion for dispersing the droplet aerosol radially, and a flow path through which the droplet aerosol moves is formed; a first heater surrounding an outer surface of the first housing and heating the first housing; and a second heater positioned inside the second housing and heating the second housing.

The first housing is be formed with a double-tube structure including an inner tube and an outer tube, and a plurality of hole-shaped first flow paths through which the droplet aerosol moves may be formed between the inner tube and the outer tube.

The second housing is inserted into the inner tube, and a second flow path through which the droplet aerosol moves may be formed by a plurality of first partition walls that extend in a longitudinal direction and protrude from an outer surface.

In the second housing, a plurality of hole-shaped third flow paths through which the droplet aerosol dispersed radially from the dispersion portion moves may be formed at the upper portion, and a spiral fourth flow path through which the droplet aerosol passing through the third flow paths moves may be formed by a spiral second partition wall protruding from an outer surface.

The first heater may be a band heater.

The second heater may be a rod heater.

In the heat exchanger according to the present disclosure, the first heater surrounding the outer surface of the first housing, and the second heater can compensate for heat loss.

The heat exchanger according to the present disclosure includes the second housing that can be inserted into and separated from the inside of the first housing, thereby allowing the inside to be easily cleaned, and includes the flow paths formed inside the first and second housings, thereby expanding the surface area through which the droplet aerosol moves and increasing the vaporization efficiency.

### BRIEF DESCRIPTION OF THE DRAWINGS

FIG. 1 is a diagram showing a longitudinal section of a heat exchanger according to the first embodiment of the present disclosure.

FIG. 2 is a diagram showing a cross section of a heat exchanger according to the first embodiment of the present disclosure.

FIG. 3 is a diagram showing a cross section of a first housing according to the first embodiment of the present disclosure.

FIG. 4 is a diagram showing a cross section of a second housing according to the first embodiment of the present disclosure.

FIG. 5 is a diagram showing a cross section of a heat exchanger according to the second embodiment of the present disclosure.

FIG. 6 is a diagram showing a longitudinal section of a heat exchanger according to the second embodiment of the present disclosure.

FIG. 7 is a diagram showing a cross section of a first housing according to the second embodiment of the present disclosure.

FIG. 8 is a diagram showing a second housing according to the second embodiment of the present disclosure.

FIG. 9 is a diagram showing a cross section of a second housing according to the second embodiment of the present disclosure.

### DETAILED DESCRIPTION

In order to maintain the temperature of the vapor pressure required by a droplet aerosol in the vaporization device, a heat exchanger maintains a high temperature. However, the heat exchanger rapidly loses heat in a central portion due to the droplet aerosol sprayed from an atomizer. In other words, since the temperature in the central portion of the heat exchanger is formed relatively low, the droplet aerosol sprayed from the atomizer is not vaporized but condenses, and the time it is in contact with a flow path surface inside the heat exchanger increases, further accelerating the heat loss of the heat exchanger. Due to this heat loss of the heat exchanger, the droplet aerosol that is not vaporized may stick to the inside of the heat exchanger in the form of particles and contaminate the heat exchanger.

When cleaning the heat exchanger to remove contaminant particles stuck to the inside of the heat exchanger, there is a problem that the existing heat exchanger has many blind spots, making it difficult to completely remove the contaminant particles. In addition, even when checking whether there are contaminant particles by using an endoscopic camera and a particle counter so as to check the degree of cleaning of the heat exchanger, there is a problem that it is difficult to accurately check the presence or absence of contaminant particles due to the blind spots of the heat exchanger.

As such, the heat exchanger from which contaminant particles are not completely removed can act as a source of contamination in the process of depositing a thin-film on a wafer, leading to process failure.

Therefore, it is necessary to develop a heat exchanger that prevents the generation of contaminant particles by compensating for the heat loss occurring in the central portion of the heat exchanger and makes it easy to remove contaminant particles.

It should be noted that in the following description, only the parts necessary for understanding embodiments of the present disclosure are described, and the description of other parts will be omitted to the extent that it does not deviate from the subject matter of the present disclosure.

The terms or words used in the following description and claims should not be interpreted as limited to their usual or lexical meanings, and should be interpreted as meanings and concepts that conform to the technical idea of the present disclosure based on the principle that the inventor can appropriately define the concept of the term in order to explain his or her own invention in the best way. Therefore, embodiments disclosed in the description and configurations illustrated in the drawings are merely preferred embodiments of the present disclosure, and do not represent all of the technical idea of the present disclosure, so it should be understood that there may be various equivalents and modifications that can replace them at the time of this application.

Now, embodiments of the present disclosure will be described in detail with reference to the accompanying drawings.

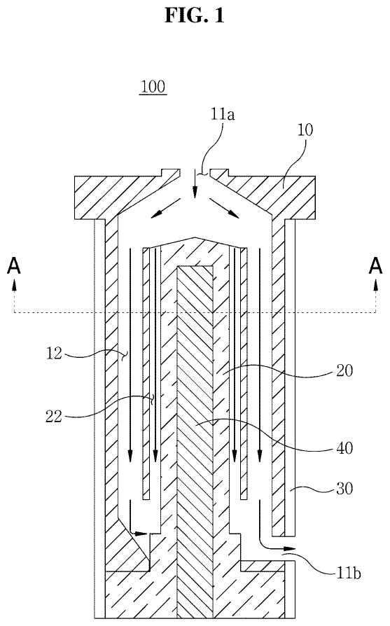

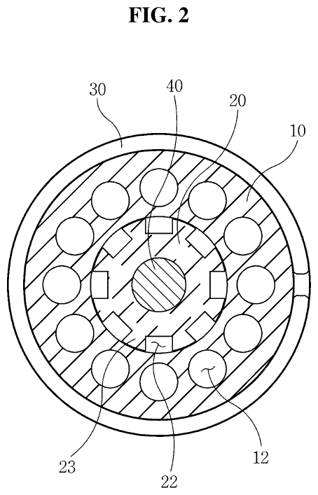

FIG. 1 is a diagram showing a longitudinal section of a heat exchanger according to the first embodiment of the present disclosure, and FIG. 2 is a diagram showing a cross section of a heat exchanger according to the first embodiment of the present disclosure.

Referring to FIGS. 1 and 2, a heat exchanger 100 according to the first embodiment of the present disclosure includes a first housing 10 in which an inlet 11a through which droplet aerosol flows in is formed at an upper portion and an outlet 11b through which a vapor formed by vaporizing the droplet aerosol flows out is formed at a lower portion, a second housing 20 inserted into the first housing 10 and in which a flow path through which droplet aerosol moves is formed, a first heater 30 surrounding the outer surface of the first housing 10 and heating the first housing 10, and a second heater 40 positioned inside the second housing 20 and heating the second housing 20.

The heat exchanger 100 allows the droplet aerosol introduced through the inlet 11a to be vaporized firstly at the upper portion and vaporized secondly while passing through first and second flow paths 12 and 22, and the vapor formed thereby to flow out through the outlet 11b.

Hereinafter, the configuration of the heat exchanger 100 according to the first embodiment of the present disclosure will be described in more detail.

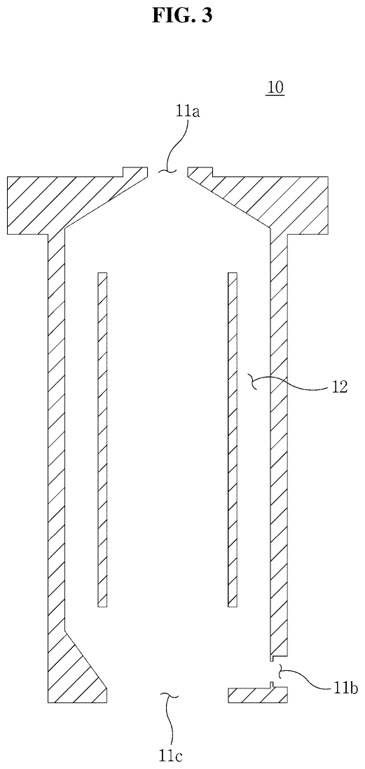

FIG. 3 is a diagram showing a cross section of a first housing 10 according to the first embodiment of the present disclosure.

Referring to FIGS. 1 to 3, in the first housing 10, the inlet 11a through which droplet aerosol flows in may be formed at the upper portion, and the outlet 11b through which a vapor formed by vaporizing the droplet aerosol flows out and a first insertion port 11c through which the second housing 20 is inserted may be formed at the lower portion.

Specifically, the first housing 10 is formed with a double-tube structure including an inner tube and an outer tube, a plurality of hole-shaped first flow paths 12 through which droplet aerosol moves may be formed between the inner tube and the outer tube, and the second housing 20 may be inserted into the inner tube. The first heater 30 is a band heater, and surrounds the outer surface of the first housing 10 to heat the first housing 10, thereby allowing the droplet aerosol existing inside the first housing 10 to be vaporized.

The first flow paths 12 can supply heat energy to the droplet aerosol in a short period of time by expanding the surface area over which the droplet aerosol moves.

When such a flow path is formed in a central portion of the first housing 10, i.e., inside the inner tube, the effect of expanding the surface area through which the droplet aerosol moves can be obtained. However, there is a problem that heat loss occurs quickly in the central portion of the first housing 10, so that the vaporization of the droplet aerosol does not occur smoothly. In addition, when the flow path is formed in the central portion of the first housing 10, the structure of the heat exchanger 100 becomes complicated, so there is a problem that the first housing 10 is difficult to clean.

The heat exchanger 100 according to the first embodiment of the present disclosure includes the second housing 20 that can be inserted into and separated from the inside of the first housing 10, thereby allowing the inside to be easily cleaned, and includes the flow paths formed inside the first and second housings 10 and 20, thereby expanding the surface area through which the droplet aerosol moves and increasing the vaporization efficiency.

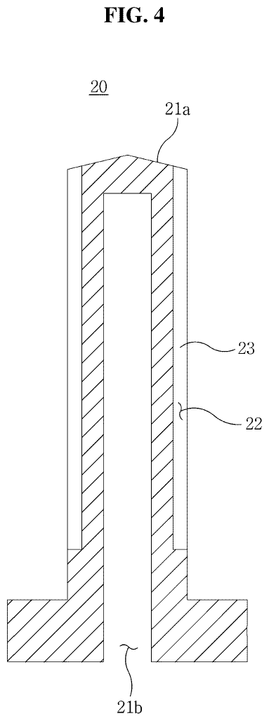

FIG. 4 is a diagram showing a cross section of a second housing 20 according to the first embodiment of the present disclosure.

Referring to FIGS. 1 to 4, in the second housing 20, a dispersion portion 21a may be formed at the upper portion to disperse the droplet aerosol radially, and the second flow path 22 through which the droplet aerosol moves may be formed by a plurality of first partition walls 23 that extend in a longitudinal direction and protrude from the outer surface. In addition, in the second housing 20, a second insertion port 21b may be formed into which the second heater 40 is inserted. The second heater 40 is a rod heater, and is positioned inside the second housing 20 to heat the second housing 20, thereby allowing the droplet aerosol existing outside the second housing 20 to be vaporized. The second heater 40 is positioned at the central portion of the heat exchanger 100 to compensate for heat loss occurring at the central portion.

If the droplet aerosol is stuck together while moving through the first housing 10, vaporization may not occur well. Therefore, the second housing 20 may have the cone-shaped dispersion portion 21a formed at the upper portion so that the droplet aerosol flowing in through the inlet 11a can be radially dispersed within the first housing 10.

The second housing 20 can be inserted into the first housing 10 so that its outer surface is spaced apart from the inner tube of the first housing 10. The droplet aerosol dispersed radially from the dispersion portion 21a can move to this separation space. In the second housing 20, the second flow path 22 through which the droplet aerosol moves may be formed by the first partition wall 23 that extends lengthwise and protrudes from the outer surface. The second flow path 22 expands the surface area over which the droplet aerosol moves, thereby allowing vaporization to occur well.

The heat exchanger according to the present disclosure is not limited to the above-described shape, and may include a heat exchanger according to the second embodiment.

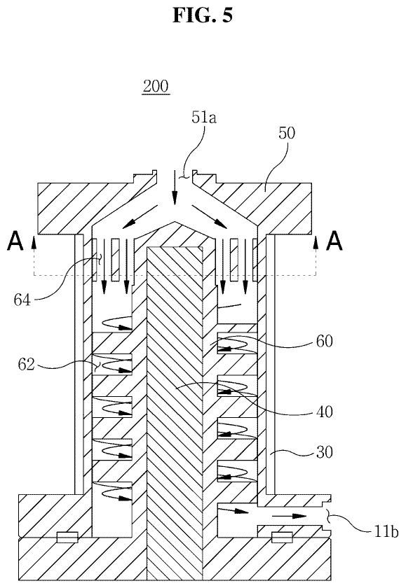

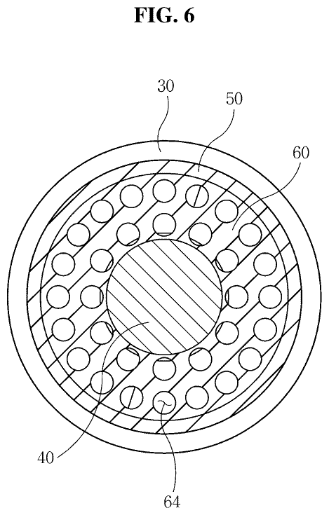

FIG. 5 is a diagram showing a cross section of a heat exchanger according to the second embodiment of the present disclosure, and FIG. 6 is a diagram showing a longitudinal section of a heat exchanger according to the second embodiment of the present disclosure.

Referring to FIGS. 5 and 6, a heat exchanger 200 according to the second embodiment of the present disclosure includes a first housing 50 in which an inlet 51a through which droplet aerosol flows in is formed at an upper portion and an outlet 51b through which a vapor formed by vaporizing the droplet aerosol flows out is formed at a lower portion, a second housing 60 inserted into the first housing 50 and in which a flow path through which droplet aerosol moves is formed, a first heater 30 surrounding the outer surface of the first housing 50 and heating the first housing 50, and a second heater 40 positioned inside the second housing 60 and heating the second housing 60.

The heat exchanger 200 allows the droplet aerosol introduced through the inlet 51a to be vaporized firstly while passing through a third flow path 64 formed at the upper portion of the second housing 60 and vaporized secondly while passing through a spiral fourth flow path 62, and the vapor formed thereby to flow out through the outlet 51b.

Hereinafter, the configuration of the heat exchanger 200 according to the second embodiment of the present disclosure will be described in more detail.

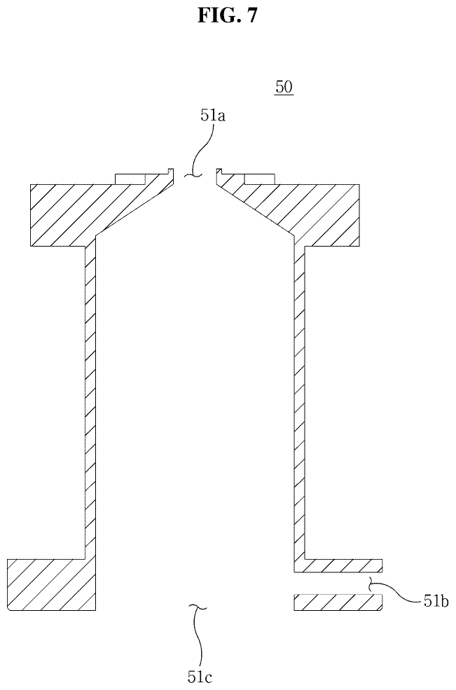

FIG. 7 is a diagram showing a cross section of a first housing 50 according to the second embodiment of the present disclosure.

Referring to FIGS. 5 to 7, in the first housing 50, the inlet 51a through which droplet aerosol flows in may be formed at the upper portion, and the outlet 51b through which a vapor formed by vaporizing the droplet aerosol flows out and a first insertion port 51c through which the second housing 60 is inserted may be formed at the lower portion. The first heater 30 is a band heater, and surrounds the outer surface of the first housing 50 to heat the first housing 50, thereby allowing the droplet aerosol existing inside the first housing 50 to be vaporized.

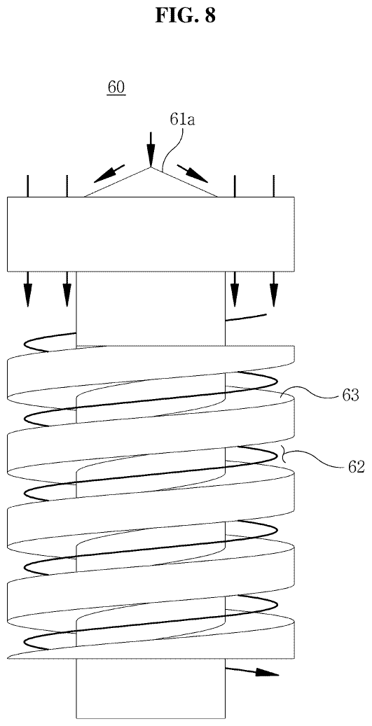

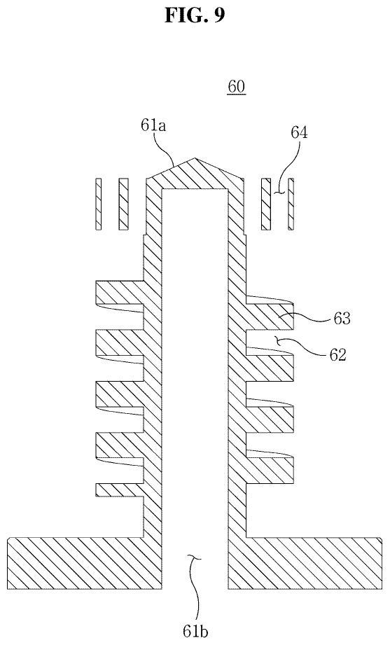

FIG. 8 is a diagram showing a second housing 60 according to the second embodiment of the present disclosure, and FIG. 9 is a diagram showing a cross section of a second housing 60 according to the second embodiment of the present disclosure.

Referring to FIGS. 5 to 9, in the second housing 60, a dispersion portion 61a for radially dispersing the droplet aerosol and the plurality of hole-shaped third flow path 64 for moving the droplet aerosol may be formed at the upper portion, and the spiral fourth flow path 62 may be formed by a spiral second partition wall 63 protruding from the outer surface. In addition, in the second housing 60, a second insertion port 61b may be formed into which the second heater 40 is inserted. The second heater 40 is a rod heater, and is positioned inside the second housing 60 to heat the second housing 60, thereby allowing the droplet aerosol existing outside the second housing 60 to be vaporized. The second heater 40 is positioned at the central portion of the heat exchanger 200 according to the second embodiment to compensate for heat loss occurring at the central portion.

Similar to the second housing 60 according to the first embodiment, the second housing 60 according to the second embodiment may have the cone-shaped dispersing portion 61a formed at the upper portion so that the droplet aerosol flowing in through the inlet 51a can be radially dispersed within the first housing 50.

The droplet aerosol radially dispersed along the dispersion portion 61a can pass through the third flow path 64 formed in the shape of multiple holes. The third flow path 64 can increase the surface area over which the droplet aerosol moves so that vaporization can occur well. Since the droplet aerosol receives sufficient thermal energy in the process of passing through the third flow path 64, most of the introduced droplet aerosol can be vaporized in the process of passing through the third flow path 64. That is, the droplet aerosol can be radially dispersed along the dispersion portion 61a and can move smoothly without stagnation through the linearly formed third flow path 64.

The vapor and the droplet aerosol that is not vaporized in the third flow path 64 can move along the spiral fourth flow path 62. The fourth flow path 62 is formed in a spiral shape to not only increase the surface area over which the droplet aerosol moves, but also increase the time that the droplet aerosol remains inside the first housing 50, thereby facilitating vaporization.

Meanwhile, the embodiments disclosed in the description and drawings are merely specific examples presented to help understanding and are not intended to limit the scope of the present disclosure. It is apparent to those skilled in the art to which the present disclosure pertains that other modifications based on the technical idea of the present disclosure can be implemented in addition to the embodiments disclosed herein.

1. A heat exchanger for a vaporization device, comprising:
a first housing in which an inlet through which droplet aerosol flows in is formed at an upper portion, the droplet aerosol flowing in is vaporized firstly at the upper portion, the droplet aerosol remaining after the first vaporization is vaporized secondly at a lower portion, and an outlet through which a vapor formed by vaporizing the droplet aerosol flows out is formed at the lower portion;
a second housing inserted into the first housing, and in which a cone-shaped dispersion portion is formed at the upper portion for dispersing the droplet aerosol radially, and a flow path through which the droplet aerosol moves is formed;
a first heater surrounding an outer surface of the first housing and configured to heat the first housing; and
a second heater positioned inside the second housing and configured to heat the second housing.

2. The heat exchanger of claim 1, wherein the first housing is formed with a double-tube structure including an inner tube and an outer tube, and a plurality of hole-shaped first flow paths through which the droplet aerosol moves are formed between the inner tube and the outer tube.

3. The heat exchanger of claim 2, wherein the second housing is inserted into the inner tube, and a second flow path through which the droplet aerosol moves is formed by a plurality of first partition walls that extend in a longitudinal direction and protrude from an outer surface.

4. The heat exchanger of claim 1, wherein in the second housing, a plurality of hole-shaped third flow paths through which the droplet aerosol dispersed radially from the dispersion portion moves are formed at the upper portion, and
wherein a spiral fourth flow path through which the droplet aerosol passing through the third flow paths moves is formed by a spiral second partition wall protruding from an outer surface.

5. The heat exchanger of claim 1, wherein the first heater comprises a band heater.

6. The heat exchanger of claim 1, wherein the second heater comprises a rod heater.
